(19) United States
(12) Patent Application Publication
(10) Pub. No.: US 2026/0353676 A1
(43) Pub. Date: Nov. 5, 2026

(54) MEMCAPACITIVE COMPONENT AND METHOD FOR OPERATING THE MEMCAPACITIVE COMPONENT

(71) Applicant: SEMRON GmbH, Dresden (DE)

(72) Inventor: Kai-Uwe DEMASIUS, Dresden (DE)

(21) Appl. No.: 19/484,346

(22) PCT Filed: May 15, 2024
(86) PCT No.: PCT/DE2024/100445

§ 371 Date: Nov. 13, 2025

(30) Foreign Application Priority Data
May 16, 2023 (DE) 10 2023 001 999.2

(51) Int. Cl. H10B 99/00; G11C 11/24

(52) U.S. Cl. CPC H10B 99/14; G11C 11/24

(57) ABSTRACT

A memcapacitive component for operation with nonlinear capacitance-voltage curves is provided. The memcapacitive component comprises a number of electrical terminals for electrical contacting of the memcapacitive component, a first electrode and a second electrode. The memcapacitive component also comprises at least one dielectric disposed between the first electrode and the second electrode. The electrical terminals, the electrodes and/or the at least one dielectric comprises charge capture points for capturing variable charge amounts, said charge capture points forming potential wells of different depth. A method for operating the memcapactive component is also provided.

### CROSS-REFERENCE TO RELATED APPLICATIONS

This application is a national stage filing under 35 U.S.C. § 371 of International Application No. PCT/DE2024/100445, filed May 15, 2024, which claims priority to German patent application 102023001999.2, filed May 16, 2023. The entire contents of these applications are hereby incorporated by reference in their entirety.

### FIELD OF THE INVENTION

The present disclosure relates in general to microelectronic devices. In particular, the present disclosure relates to a memcapacitive device and a method for operating the memcapacitive device.

### BACKGROUND OF THE INVENTION

Particularly in connection with recent developments in the field of artificial intelligence (AI) and artificial neural networks, such as transformer models, increasingly powerful and faster computers are needed. New processor and memory architectures designed specifically for AI-typical operations, such as tensor multiplication, could help meet these growing demands.

Patent publication US2022059161A1 describes a memcapacitive device or capacitive synaptic device, as well as a matrix of a plurality of capacitive synaptic devices for performing vector-matrix multiplication. Compared to memristive devices, memcapacitive devices offer several advantages in terms of static power consumption and sneak path problems that can occur with memristive devices.

Volatile and free vector-matrix multiplications can play a decisive role in the calculation of transformer models in the so-called attention layers or in the implementation of short-term memory. In this context, free multiplication means that the same multiplication operation can be routinely repeated with different or freely variable weights or matrix parameters. The speed and flexibility of changing weights or matrix elements between individual calculation steps plays a crucial role in increasing the efficiency of AI computers and artificial neural networks.

### SUMMARY OF THE INVENTION

One objective of embodiments of the present disclosure is to provide a memcapacitive device and a method for operating the memcapacitive device, which enable fast and flexible changing of weights in matrix operations.

To solve this task, a first aspect proposes a memcapacitive device, hereinafter also referred to as an “arrangement”, for operation under nonlinear capacitance-voltage curves. In particular, the memcapacitive device can be designed as a semiconductor device with variable nonlinear behavior or with an adjustable nonlinear capacitance-voltage curve.

The memcapacitive component comprises a number of electrical connections for electrically contacting the memcapacitive component. In particular, the number of electrical connections may comprise one, two, three, or four electrical connections.

The memcapacitive component comprises a first electrode and a second electrode. The memcapacitive component further comprises at least one dielectric arranged between the first electrode and the second electrode, wherein the electrical connections and/or the at least one dielectric have charge traps forming potential wells of different depths for trapping variable, in particular controllably variable, amounts of charge.

In particular, the memcapacitive device may have at least one energetically shallow charge trap for short-term or volatile storage of charges or capacitance values and at least one energetically deep charge trap for long-term or non-volatile storage of charges or capacitance values. The energetically shallow or energetically deep charge traps can, in particular, form potential wells with correspondingly low or high threshold or activation energies or barrier heights.

Due in particular to the ability of the memcapacitive component to store different states or charge quantities, the memcapacitive component can be used to store computing parameters and perform computing operations. The value of a computing parameter can be represented at least indirectly by a stored charge quantity. The potential wells associated with energetically flat charge traps for short-term storage can have a depth or barrier height of at most 1.2 eV, or between 0.2 eV and 1.1 eV, or between 0.5 eV and 0.9 eV.

The potential wells associated with energetically deep charge traps for long-term or non-volatile storage can have a depth or barrier height of at least 1.6 eV, or between 1.7 eV and 3.0 eV, or between 2.0 eV and 2.5 eV. The ratio of the depth or barrier height of potential wells associated with energetically shallow charge traps for short-term storage to potential wells associated with energetically deep charge traps for long-term or non-volatile storage may be at least 0.01 or at most 0.99 or between 0.05 and 0.95 or between 0.1 and 0.9 or between 0.2 and 0.8 or between 0.4 and 0.6.

The at least one dielectric may comprise a first dielectric with a first charge trap and a second dielectric with a second charge trap. By using different dielectrics, charge traps with different energy depths can be realized. For example, the charge trap of the first dielectric may have a lower energy depth than the charge trap of the second dielectric. The potential well formed by the first charge trap can be used in particular for volatile storage of charges, and the potential well formed by the second charge trap can be used for non-volatile storage of charges.

The memcapacitive device may comprise a shielding layer arranged between the first electrode and the second electrode with a controllably variable shielding capability. In particular, the shielding layer may be designed to shield an electric field emanating from the first electrode and/or the second electrode, whereby the shielding layer may exhibit different shielding behavior depending on the operating state.

The first dielectric may be arranged between the first electrode and the shielding layer, and/or the second dielectric may be arranged between the second electrode and the shielding layer. In particular, the two dielectrics may be arranged such that fields prevailing in the first dielectric and in the second dielectric can be shielded from each other.

The shielding layer may comprise a semiconductor layer with a controllably variable charge carrier concentration. Depending on the concentration of the charge carriers, in particular electrons or holes, the field emanating from the first electrode and/or the second electrode can be shielded to varying degrees by the shielding layer. The charge carrier concentration in the shielding layer can thus influence the shielding capacity or the measurable capacitance of the memcapacitive component. The capacitance or capacitive behavior of the memcapacitive component can thus be used to represent a variable or volatile parameter.

The shielding layer can be designed to assume quasi-static states or charge states with varying degrees of shielding capacity. In this context, quasi-static means that the charge states, in particular the charge carrier concentration or shielding capacity of the shielding layer, can be maintained for a certain period of time or during a certain dwell time. For example, the shielding layer can have a specific charge state during the execution of a computing operation or an elementary computing step. The dwell time of the charge states in the shielding layer can be set or changed in particular by internal factors, such as doping and/or charge traps, as well as externally, such as by applying a voltage or bias voltage. The ability of the shielding layer to maintain or store its state or charge state for at least a short time can represent a further or additional storage mechanism, for example, to store rapidly or frequently changing parameters for a short time before performing a calculation operation. The memcapacitive component can thus be used to implement various mechanisms for storing charges or capacitance values. In particular, the shielding layer, similar to the charge traps in the first dielectric and/or in the second dielectric, can be used to store information or parameters.

In particular, the charge traps of the first and/or second dielectric and the shielding layer can have differently stable charge states. Due to the energetic differences, both volatile and non-volatile memories can be implemented using such memcapacitive components. The first dielectric and/or the second dielectric can be designed essentially similarly to a gate stack in a flash memory, whereby the two dielectrics can have charge trap sites with different energetic depths.

The first electrode and/or the second electrode may be designed to store a capacitance value for a short period of time by means of charge storage on the electrodes. In particular, due to the nonlinear capacitance-voltage curve, capacitance values can be used to represent calculation parameters, in particular parameters that need to be stored temporarily. The memcapacitive component may be used in particular in a circuit or used in a circuit arrangement with an external capacitor. In particular, the external capacitor may be connected with a first terminal to one of the electrodes of the memcapacitive component and electrically connected via a switch to a storage voltage. The other terminal of the capacitor may in particular be connected to a readout signal. The external capacitor can be designed in particular to store a storage voltage, so that a capacitance value of the memcapacitive component can be set by means of the storage voltage. In particular, potential wells of different depths can be implemented by means of the switch. During writing, the depth of a potential well can be reduced so that charges can be added to the potential well. During storage, the depth of the potential well can be increased so that the charges can be stored. Depending on the height of the potential well, short-term or long-term storage can be enabled. In particular, a deep potential well means the switch is open, a shallow potential well or no potential well means the switch is closed. In principle, any intermediate stages are possible in order to achieve different depths of the potential wells, for example with an integrated field-effect transistor, see FIG. 8 below.

The number of electrical terminals may comprise at least one electrical terminal for contacting the shielding layer, so that capacitance values can be stored temporarily by means of charge storage on the shielding layer. In particular, the shielding layer of the memcapacitive component may have at least one electrical connection of its own for directly contacting the shielding layer, via which electrical charges can be injected into the shielding layer or withdrawn from the shielding layer. The memcapacitive component can be used in particular in a circuit or circuit arrangement with an external capacitor connected to the shielding layer for setting the short-term capacitance value.

The external capacitor may, for example, be connected with a first terminal to a switch which connects or disconnects the storage voltage, whereby the second terminal of the capacitor may be connected to ground. In particular, due to the nonlinear capacitance-voltage curve of the memcapacitive component, capacitance values can be used to represent computing parameters that are stored too short-term or too volatilely.

In some embodiments, the shielding layer has a p-doped region and an n-doped region, wherein the p-doped region or the n-doped region may be designed to be electrically contacted via at least one switch with a bias voltage or with a constant voltage. Via the p-doped region and/or the n-doped region, charge carriers can be injected into the shielding layer or removed from the shielding layer in order to control the charge state or shielding capacity of the shielding layer. In particular, the shielding layer may have a pin-diode topology, whereby the dielectric between the p-doped region and the n-doped region can serve as a shielding region for shielding the field emanating from the first electrode or the second electrode.

The memcapacitive device may comprise at least one field-effect transistor at least partially integrated into the shielding layer for connecting the p-doped region and/or the n-doped region to a bias voltage. In particular, at least some of the components of the at least one field-effect transistor and the memcapacitive device may have been manufactured in common process steps. In this case, the n-doped region of the memcapacitive device can function as the source or drain of the field-effect transistor, thereby achieving a particularly compact design. The field-effect transistor can in particular act as the switch for connecting the memcapacitive component and the external capacitor to the storage voltage.

In some embodiments, the memcapacitive device is designed such that the first electrode and/or the second electrode does not overlap with the n-doped region and/or with the p-doped region. In particular, the area between the p-doped region and the n-doped region may extend beyond the lateral extent of the first and/or second electrodes in at least one lateral direction. In this way, it is possible to prevent the p-doped region and/or the n-doped region from impairing the shielding function of the shielding layer.

A second aspect provides a method for operating a memcapacitive component. The memcapacitive component can be designed in particular as a memcapacitive component with an adjustable nonlinear capacitance-voltage curve according to an embodiment according to the first aspect. In particular, the memcapacitive component has a number of terminals, wherein the number of terminals comprises a first electrode and a second electrode. The memcapacitive component further comprises at least one dielectric arranged between the first electrode and the second electrode, wherein the electrical terminals and/or the at least one dielectric have charge traps forming potential wells of varying depths for trapping variable, in particular controllably variable, amounts of charge.

The method comprises writing the memcapacitive device by applying a positive or negative write voltage to the first electrode and/or to the second electrode in order to change the amounts of charge trapped in the potential wells. When writing the memcapacitive device, a measurable change in the state of the memcapacitive device may occur, in particular. Applying the write voltage can, in particular, cause such a measurable change in the state of the memcapacitive component. For example, applying the write voltage can lead to tunneling between the first or second electrode and the at least one charge trap, so that the amount of charge stored at the charge trap can be changed. This change in state can be measured or read out, for example, in a subsequent step. In particular, the change in the amount of charge stored at the at least one charge trap can have an effect on the capacitive behavior of the memcapacitive device, which can also be measured.

The first dielectric may be arranged between the first electrode and the shielding layer, and the second dielectric may be arranged between the second electrode and the shielding layer, wherein the first dielectric and/or the second dielectric may comprise at least one charge trap for storing a variable amount of charge.

In some embodiments, the method comprises adjusting a nonlinear capacitance-voltage curve. The nonlinear capacitance-voltage curve can be set in particular by changing the charge states of the at least one charge trap or the shielding layer. This can be done in particular by an external voltage or an external field, which can cause charge shifts in the memcapacitive device, in particular in the dielectrics or in the shielding layer. A current nonlinear capacitance-voltage curve can be used to describe a current state of the memcapacitive component, so that the capacitance or the nonlinear capacitance-voltage curve can be used to represent variable parameters, such as weights in a matrix-vector multiplication.

The at least one dielectric may comprise a first dielectric with a first charge trap and a second dielectric with a second charge trap. By using different dielectrics, charge traps with different energy depths can be realized. For example, the charge trap of the first dielectric may have a lower energy depth than the charge trap of the second dielectric.

The memcapacitive component may comprise a shielding layer arranged between the first electrode and the second electrode with a controllably variable shielding capacity, wherein the adjustment of the nonlinear capacitance-voltage curve may comprise applying a bias voltage, in particular a constant bias voltage, to the shielding layer. Applying the bias voltage can, in particular, change the charge state of the shielding layer and thus the shielding behavior of the shielding layer, which can influence the capacitive behavior of the memcapacitive device.

The first dielectric may be arranged between the first electrode and the shielding layer and/or the second dielectric may be arranged between the second electrode and the shielding layer. In particular, the two dielectrics may be arranged such that fields present in the first dielectric and in the second dielectric can be shielded from each other.

In some embodiments of the method, the shielding layer comprises a p-doped region and an n-doped region, wherein the p-doped region and the n-doped region can be configured to be electrically connected via at least one switch with a bias voltage. Applying the bias voltage may comprise applying a constant voltage in the p-doped region and/or in the n-doped region.

In particular, the p-doped region and the n-doped region may be connected to a constant voltage or ground during the application of the write voltage, wherein, before resetting the write voltage to the initial value, the n-or p-doped region is disconnected from the constant voltage or ground. In particular, the bias voltage of the shielding layer may be maintained throughout the entire duration of the write process, so that the write process can take place under essentially constant conditions. In some embodiments, when the bias voltage is applied, a pin diode formed by the p-doped region and n-doped region in the shielding layer is operated in the forward direction. By operating the pin diode in the forward or forward-current direction, electrons can be injected into the shielding layer.

In some embodiments, the method comprises applying a readout voltage to the first electrode and/or the second electrode to read out the memcapacitive device. In particular, the readout may be performed in a separate process step in order to read out a parameter value stored in the memcapacitive device or the current state of the memcapacitive device at a later point in time, if necessary.

### BRIEF DESCRIPTION OF THE SEVERAL VIEWS OF THE DRAWINGS

The invention will now be explained in more detail with reference to the accompanying figures. The same reference numerals are used in the figures for identical or similarly functioning parts.

FIG. 1 shows a schematic cross-section through a memcapacitive component according to a first embodiment,

FIG. 2 shows a schematic cross-section through a memcapacitive device according to a second embodiment,

FIG. 3 shows the memcapacitive device of FIG. 2 together with a nonlinear capacitance-voltage curve,

FIG. 4 shows an electrical circuit with a memcapacitive device according to FIG. 2 and with an external capacitor according to an embodiment,

FIG. 5 shows an electrical circuit with a memcapacitive device according to FIG. 2 and with an external capacitor according to a further embodiment,

FIG. 6 shows an electrical circuit with a memcapacitive component according to a third embodiment,

FIG. 7 shows an electrical circuit with a memcapacitive component according to a fourth embodiment,

FIG. 8 shows an electrical circuit with a memcapacitive component according to a fifth embodiment, and

FIG. 9 shows a flowchart of a method for operating a memcapacitive device according to an embodiment.

### DETAILED DESCRIPTION

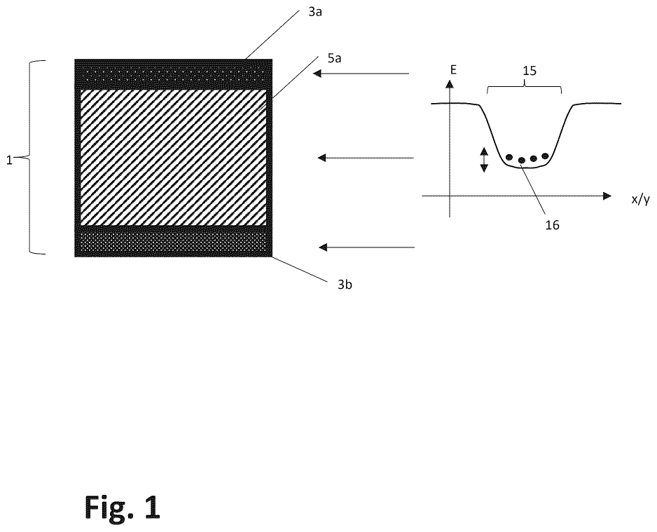

FIG. 1 shows a schematic cross-section of a memcapacitive device according to a first embodiment.

In the embodiment shown, the memcapacitive device 1 comprises a first electrode 3a, a second electrode 3b, and a dielectric 5a arranged between the first electrode 3a and the second electrode 3b.

The memcapacitive device 1 has a variable nonlinear capacitance-voltage curve and charge traps (not shown) with different energy depths. In particular, the first electrode 3a, the second electrode 3b, and/or the dielectric 5a may have charge traps forming potential wells of varying depths for trapping variable amounts of charge. This is illustrated in FIG. 1 by a simplified potential well 15 with charge carriers 15 trapped therein, shown on the right side of the figure. The arrows pointing to the left indicate those areas of the memcapacitive device 1 where the charge traps may be located.

The nonlinear capacitance-voltage curve of the memcapacitive component can be shifted depending on the voltage or charge state of the electrodes 3a, 3b, and the dielectric 5a. In particular, the charge traps may be designed so that the respective charge state can be stored quickly and temporarily and changed quickly.

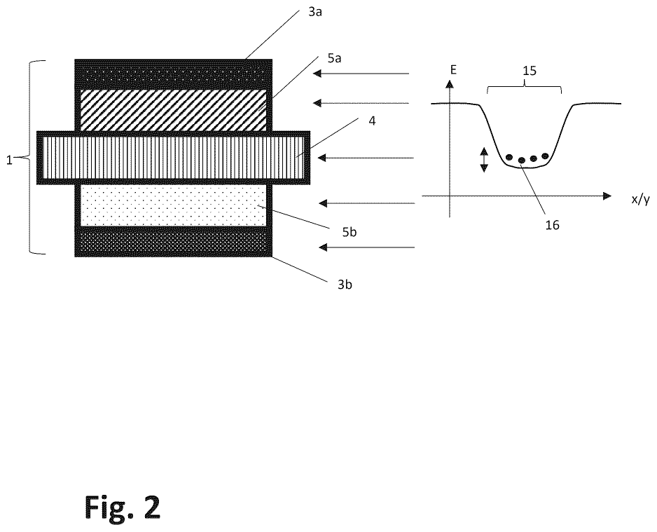

FIG. 2 shows a schematic cross-section of a memcapacitive component according to a second embodiment. The second embodiment essentially corresponds to the first embodiment, whereby the memcapacitive component comprises a first dielectric 5a, a second dielectric 5b, and a shielding layer 4, wherein the first dielectric 5a is arranged between the first electrode 3a and the shielding layer 4, and wherein the second dielectric 5b is arranged between the second electrode 3b and the shielding layer 4.

The shielding layer 4 has a semiconductor layer with a variable charge carrier concentration. The first dielectric 5a has a first charge trap (not shown) for storing a variable amount of charge. The charge trap can be designed in particular for non-volatile storage of the charge, which can be used in particular for non-volatile storage of a parameter value. In some embodiments, the second dielectric 5b also has a charge trap or second charge trap for storing a variable amount of charge. FIG. 2 also shows a simplified representation of a potential well 15 with charge carriers 15 trapped therein and left-pointing arrows to indicate the areas of the memcapacitive device in which the charge traps may be located.

The nonlinear capacitance-voltage curve can be shifted depending on the voltage or charge state of the electrodes 3a, 3b, the shielding layer 4, or the dielectrics 5a, 5b. The charge state of the shielding layer 4 or shielding electrode can be stored quickly and transiently and changed rapidly.

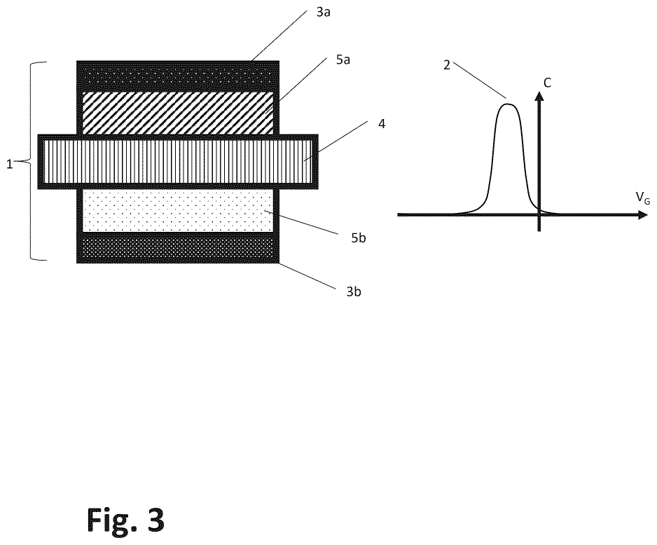

FIG. 3 shows the memcapacitive component according to FIG. 2 together with a nonlinear capacitance-voltage curve. In particular, a simplified capacitance-voltage dependence is shown on the right side of the figure to illustrate the nonlinear capacitance-voltage curve.

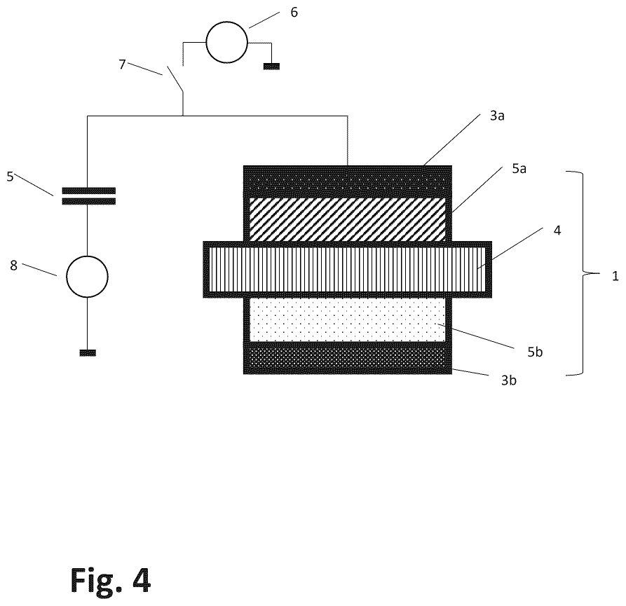

FIG. 4 shows an electrical circuit with a memcapacitive component according to FIG. 2 and with an external capacitor. The external capacitor 5 is designed to store a storage voltage or write voltage. In the circuit shown in FIG. 4, the external capacitor 5 is connected with a first terminal to the first electrode 3a of the memcapacitive component 1 and to a storage voltage 6 via a switch 7. The external capacitor 5 is connected with a second terminal to a readout signal 8. The stored charge on the capacitor 5 causes a shift in the capacitance-voltage curve of the memcapacitive device 1 and thus sets the capacitance value of the memcapacitive device 1.

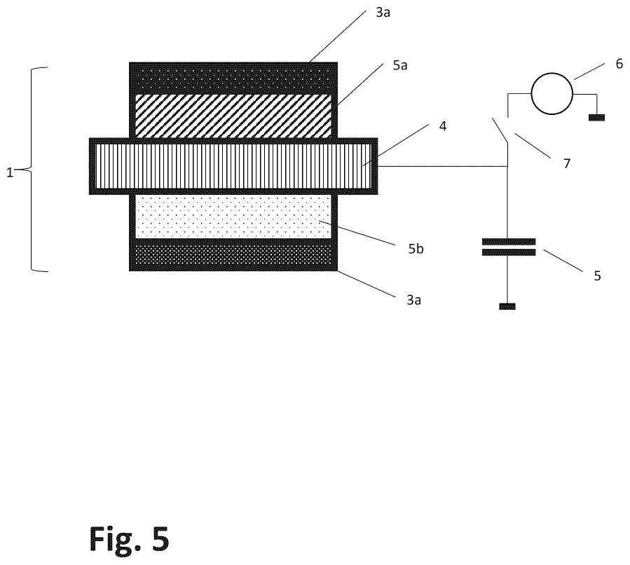

FIG. 5 shows an electrical circuit with a memcapacitive component according to FIG. 2 and with an external capacitor 5 according to a further embodiment. The circuit shown in FIG. 5 essentially corresponds to the embodiment of FIG. 4, wherein the external capacitor 5 is connected to the shielding layer 4 of the memcapacitive component 1. The charge on the capacitor 5 also causes a shift in the capacitance-voltage curve 2 of the memcapacitive component 1.

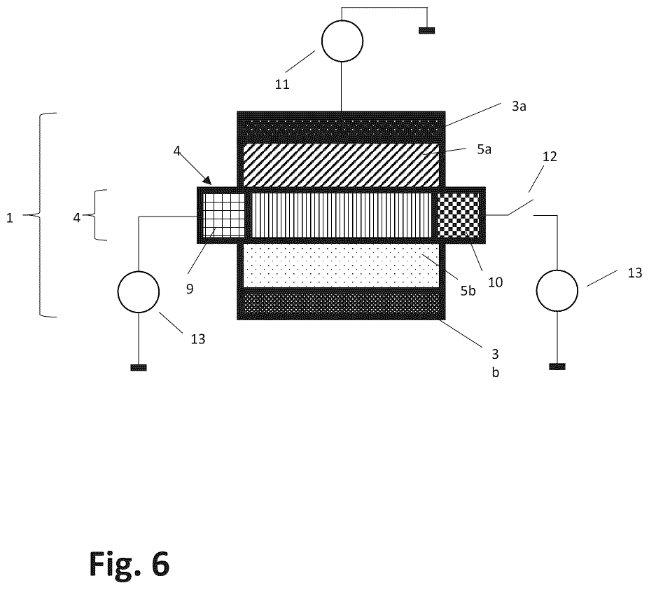

FIG. 6 shows an electrical circuit with a memcapacitive component according to a third embodiment. The memcapacitive component 1 according to the third embodiment is essentially similar to the memcapacitive component 1 according to the second embodiment, cf. FIGS. 2 to 4 above. In particular, the memcapacitive device 1 of FIG. 5 also comprises a first electrode 3a, a second electrode 3b, a first dielectric 5a, a second dielectric 5b, and a shielding layer 4, wherein the shielding layer 4 has a p-doped region 9 and an n-doped region 10. The p-doped region 9 and the n-doped region 10 are formed at two opposite lateral ends of the shielding layer 4.

In the circuit shown, a writing voltage 11 is applied to the first electrode 3a of the memcapacitive device 1. The n-doped region 10 of the shielding layer is connected to a constant voltage 13 via a switch 12. During operation, switch 12 can be opened after the write voltage 11 has been applied, so that the injected electrons can remain in the shielding layer 4 when the write voltage is reset to its initial value.

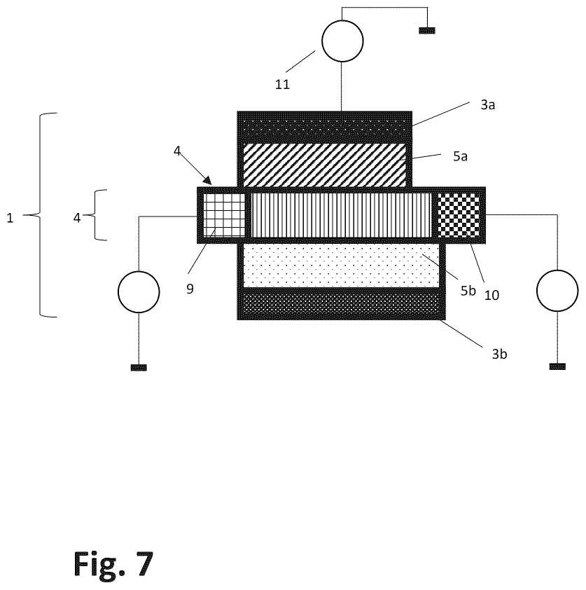

FIG. 7 shows an electrical circuit with a memcapacitive device according to a fourth embodiment. The fourth embodiment of the memcapacitive device essentially corresponds to the third embodiment shown in FIG. 6, wherein the memcapacitive device 1 is designed such that the first electrode 3a does not overlap with the n-doped region 10 of the shielding layer 4. In particular, the first electrode 3a has a smaller lateral extent than, for example, the first electrode 3a according to the embodiment of FIG. 4, so that the first electrode 3a does not reach the n-doped region 10 of the shielding layer 4.

In order to inject electrons into the shielding layer 4, the pin diode formed by the p-doped region 9 and the n-doped region 10 in the shielding layer 4 can be operated in the forward direction.

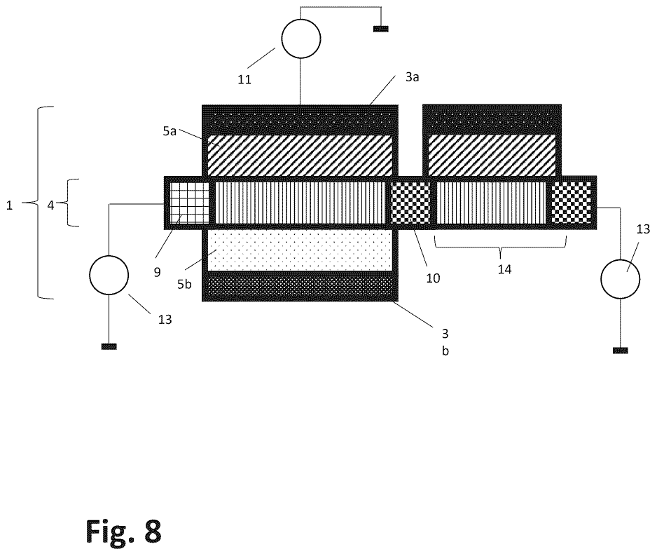

FIG. 8 shows an electrical circuit with a memcapacitive component according to a fifth embodiment. The fifth embodiment essentially corresponds to the third embodiment according to FIG. 6, whereby the memcapacitive component 1 further comprises a field effect transistor 14, which is partially integrated into the shielding layer 4. The n-doped region 10 of the memcapacitive device 1 can serve as the source or drain of the field-effect transistor, thereby achieving a particularly compact design.

Manufacturing techniques used in the semiconductor industry in particular can be used to produce the memcapacitive device described above. In particular, the memcapacitive device can be designed as an essentially planar semiconductor device, which can be manufactured using processes known from semiconductor production, such as photolithography, metallization, wet and dry chemistry, and plasma processes. For example, a silicon-based semiconductor substrate can be used as shielding layer. The first and second dielectrics may comprise silicon oxide, and the charge traps may be realized in silicon nitride. The charge traps can be formed in particular as inclusions in the dielectrics, comparable to floating gates in flash memories. The p-doped region and the n-doped region can be provided by implantation and furnace steps, as known, for example, from MOSFET technology.

The memcapacitive device may be designed in particular so that the charge traps have different energy depths. For this purpose, in addition to silicon with a band gap of 1.1 eV, other semiconductor materials can also be used to create potential wells with different barrier heights.

For example, the potential wells associated with energetically flat charge traps for short-term storage may have a depth or barrier height of at most 1.2 eV, or between 0.2 eV and 1.1 eV, or between 0.5 eV and 0.9 eV. The potential wells associated with energetically deep charge traps for long-term or non-volatile storage may have a depth or barrier height of at least 1 .6 eV or between 1.7 eV and 3.0 eV or between 2.0 eV and 2.5 eV. The ratio of the depth or barrier height of potential wells associated with energetically shallow charge traps for short-term storage to potential wells associated with energetically deep charge traps for long-term or non-volatile storage may be at least 1.6 eV or between 1.7 eV and 3.0 eV or between 2.0 eV and 2.5 eV. storage, to potential wells associated with energetically deep charge traps for long-term or non-volatile storage may be at least 0.01 or at most 0.99, or between 0.05 and 0.95, or between 0.1 and 0.9, or between 0.2 and 0.8, or between 0.4 and 0.6.

The energetically flat charge traps can be used in particular for volatile storage of parameters, while the energetically deep charge traps can be used for longer-term or non-volatile storage of parameters. The shielding layer can also assume energetically shallow or quasi-static charge states, which can serve for the volatile storage of frequently changing weights or matrix element parameters.

The memcapacitive device thus combines different storage mechanisms, comparable to the short-term and long-term memory of the human brain. This could prove particularly advantageous for AI-specific computing operations.

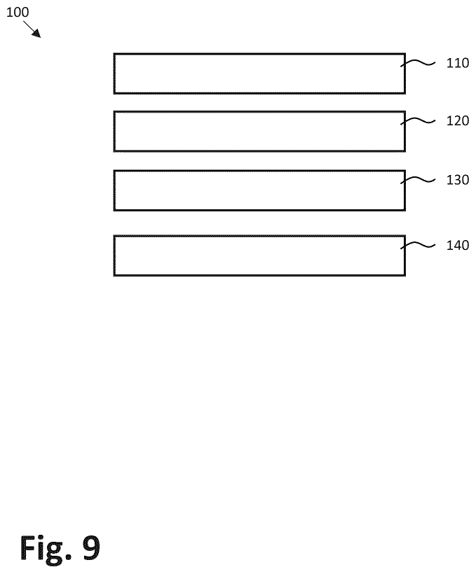

FIG. 9 shows a flowchart of a method for operating a memcapacitive device according to an embodiment. According to method 100, in a method step 110, a memcapacitive device according to the first aspect is provided. In particular, the memcapacitive device may be designed similarly to that shown in FIGS. 1 to 8.

In a process step 120, the memcapacitive component is written to by applying a write voltage. In particular, the memcapacitive device can be written to in process step 120 by applying a positive or negative write voltage to the first electrode 3a and/or the second electrode 4b in order to change the amounts of charge trapped in the potential wells. In particular, charge carriers driven by the applied write voltage can get from the first or second electrode or, if applicable, the shielding layer to the charge trap sites or leave the charge trap sites. This can be achieved in particular by Fowler-Nordheim tunneling, similar to flash memory, when charge carriers tunnel toward or away from the floating gate under the influence of an electrostatic field. Applying the write voltage can include applying a constant negative voltage, a constant positive voltage, and/or an alternating voltage. The write voltage can be applied in particular during a predefined time. In particular, the write voltage can be reset after the predefined time, in particular to an initial value.

In a process step 130, a nonlinear capacitance-voltage curve is set. Setting the nonlinear capacitance-voltage curve may in particular comprise applying a bias voltage, in particular a constant bias voltage, to the shielding layer 4. Applying the bias voltage can, in particular, change the charge state of the shielding layer 4 and thus the shielding behavior of the shielding layer, whereby the capacitive behavior of the memcapacitive device can also be changed. In the embodiments of the memcapacitive device in which the shielding layer 4 has a p-doped region and an n-doped region, applying the bias voltage may comprise applying a constant voltage in the p-doped region and/or in the n-doped region. In particular, the p-doped region and the n-doped region may be connected to a constant voltage or ground during the application of the write voltage, wherein the n-or p-doped region is disconnected from the constant voltage or ground before the write voltage is reset to the initial value.

In some implementation examples, the memcapacitive component is read out in a process step 140. In particular, a current state or a charge and/or capacitance value currently stored in the memcapacitive component can be read out in process step 140. In particular, the readout can be performed in a separate process step in order to read out a parameter value stored in the memcapacitive component or the current state of the memcapacitive component at a later point in time, if necessary. The readout can be performed in particular via an external capacitor, which can be connected to one of the electrodes of the memcapacitive device, whereby the readout signal can be measured at the second terminal of the capacitor, cf. FIG. 4 above.

The embodiments described above are merely examples and are not intended to limit the scope, applicability, or configuration of the present disclosure in any way. Rather, the foregoing description provides the skilled person with a plan for implementing at least one exemplary embodiment, whereby numerous changes may be made in the function and arrangement of the elements described in an exemplary embodiment without departing from the scope of the appended claims or their legal equivalents. In addition, multiple modules or multiple products may be connected together according to the principles described herein to obtain additional functions.

The following is a non-exhaustive list of possible examples of the inventive arrangement or the inventive method for solving the task mentioned at the outset.

Example 1. Arrangement, in particular a memcapacitive component, characterized in that the arrangement comprises energetically shallow charge traps for short-term storage of capacitance values and energetically deep charge traps for long-term storage of capacitance values.

In particular, energetically shallow charge traps can be used for the short-term storage of capacitance values and energetically deep traps can be used for the long-term storage of capacitance values.

Example 2. Arrangement according to Example 1, wherein the traps are realized in silicon nitride, and wherein deep or shallow traps can be generated depending on the selected growth parameters.

The charges in the deep traps require a longer programming time and a higher programming voltage, but can also be stored for a longer period of time. The shallow traps require a short programming time/voltage, but the charges are only stored for a short period of time.

Example 3. Arrangement according to examples 1 or 2, characterized in that the capacitive component has a non-linearity in the capacitance-voltage curve and the two electrodes are designed in such a way that capacitance values can be stored for a short period of time by means of charge storage on the electrodes.

In particular, charge storage on the electrodes can shift the capacitance-voltage curves, thereby storing a new capacitance value.

Example 4. Arrangement according to one of the preceding examples, wherein the arrangement is characterized in that the memcapacitive component has a nonlinearity in the capacitance-voltage curve and, in addition to the two electrodes, also contains a shielding layer with its own terminals, and short-term storage of capacitance values can take place by means of charge storage on the shielding layer.

In particular, the shielding layer can serve to store charges and thus to set a capacitance on the capacitance-voltage curve.

Example 5. Arrangement according to one of the preceding examples, wherein the arrangement is characterized in that a further capacitor, which stores a storage voltage for adjusting the short-term capacitance value, is connected to an electrode of the capacitive component, and the capacitor is designed to be connected to a switch which connects or disconnects the storage voltage, the other terminals of the capacitor being designed to be connected to the readout signal.

In particular, the additional capacitor can store a certain amount of charge/voltage, which is passed on to the electrode. This allows a shift along the capacitance-voltage curve to be achieved. The switch disconnects the capacitor from the storage voltage so that the value is stored and the storage voltage can be connected to other memcapacitive components and changed.

Example 6. Arrangement according to one of the preceding examples, wherein the arrangement is characterized in that a further capacitor, which stores a storage voltage for setting the short-term capacitance value, is connected to the shielding layer of the memcapacitive component, and the capacitor is designed to be connected to a switch which connects or disconnects the storage voltage, the other connection of the capacitor being designed to be connected to ground.

In particular, the capacitor is connected to the shielding layer in order to pass on the voltage to it and achieve a shift along the capacitance-voltage curve.

Example 7. Arrangement according to one of the preceding examples, wherein the arrangement is characterized in that the shielding layer contains a p-doped region and an n-doped region, in particular on the side, and the positive or negative writing voltage is connected to an electrode, and the n-or p-doped region is connected to a switch.

In particular, this embodiment can be supplemented by a method in which the positive or negative write voltage is applied to an electrode, the p-and n-doped regions are connected to a constant voltage or ground during this process, and the n-or p-doped region is disconnected from the constant voltage or ground before the write voltage is reset to its initial value.

The p-and n-regions, in particular the lateral ones, enable hole or electron injection when a negative or positive voltage is applied to the electrode. If, after applying the negative or positive voltage, the connection from the p-region or n-region to ground is disconnected and the voltage is reset, the injected holes or electrons remain in the shielding layer and are stored. The excess charge in the shielding layer causes a shift in the capacitance-voltage curve and sets a new capacitance value.

Example 8. Arrangement according to one of the preceding examples, wherein the arrangement is characterized in that the shielding layer contains a p-doped region and an n-doped region, and the positive and negative write voltages are connected to an electrode, and the electrode does not overlap with the n-doped or p-doped region.

In particular, this embodiment can be supplemented by a method in which the pin diode is operated in the forward direction when the positive or negative write voltage is applied, and the diode is operated with no voltage or in the reverse direction before the positive or negative write voltage is removed.

In this way, it is possible to dispense with a switch that controls either the p-doped or n-doped region or the additional external capacitor. This is achieved by minority carrier injection in the pin diode, which is operated in the forward direction. The minority charge carriers, together with the positive or negative write voltage at the electrode, lead to a charge carrier excess, which is stored.

Example 9. Arrangement according to one of the previous examples, wherein the arrangement is characterized in that the switch is implemented in the form of a field-effect transistor in the shielding layer.

In particular, this saves space for an additional transistor that would otherwise be required for the switch. This enables fast volatile storage similar to DRAM memory.

### LIST OF REFERENCES

1 memcapacitive component
2 nonlinearity
3a first electrode
3b second electrode
4 shielding layer
5a first dielectric 5b second dielectric
5 Capacitor
6 storage voltage
7 switch for external capacitor
8 readout signal
9 p-doped region
10 n-doped region
11 writing voltage
12 switch for doped regions
13 constant voltage
14 field-effect transistor
15 potential well
16 charge carrier

1-18. (canceled)

19. A memcapacitive device for operation under nonlinear capacitance-voltage curves, comprising:
a number of electrical terminals for electrically contacting the memcapacitive device;
a first electrode;
a second electrode; and
at least one dielectric arranged between the first electrode and the second electrode, wherein the number of electrical terminals, the electrodes and/or the at least one dielectric have charge traps forming potential wells of different depths for trapping variable amounts of charge.

20. The memcapacitive device according to claim 19, wherein the memcapacitive device has at least one energetically shallow charge trap for short-term or volatile storage of charges and at least one energetically deep charge trap for long-term or non-volatile storage of charges.

21. The memcapacitive device according to claim 19, wherein the at least one dielectric comprises a first dielectric with a first charge trap and a second dielectric with a second charge trap.

22. The memcapacitive device according to claim 19, wherein the memcapacitive device comprises a shielding layer arranged between the first electrode and the second electrode with a controllably variable shielding capability.

23. The memcapacitive device according to claim 21, wherein the first dielectric is arranged between the first electrode and the shielding layer and/or the second dielectric is arranged between the second electrode and the shielding layer.

24. The memcapacitive device according to claim 22, wherein the shielding layer comprises a semiconductor layer with a controllably variable charge carrier concentration.

25. The memcapacitive device according to claim 24, wherein the shielding layer is to assume energetically flat charge states to provide volatile storage of frequently changing weights.

26. The memcapacitive device according to claim 19, wherein the first electrode and/or the second electrode are designed for short-term storage of a capacitance value by means of charge storage on the electrodes.

27. The memcapacitive device according to claim 26, wherein the memcapacitive device comprises a circuit with an external capacitor for storing a storage voltage, wherein the external capacitor is connected with a first terminal to one of the electrodes of the memcapacitive device and is electrically connected via a switch for implementing potential wells of different depths with a storage voltage.

28. The memcapacitive device according to claim 22, wherein the number of electrical terminals comprises at least one electrical terminal for contacting the shielding layer so that short-term storage of capacitance values can take place by means of charge storage on the shielding layer.

29. The memcapacitive device according to claim 28, wherein the memcapacitive device comprises a circuit with a further capacitor for storing a storage voltage for setting one or more of the short-term capacitance values, which is connected to the shielding layer of the memcapacitive device, and wherein the capacitor is to be connected to a switch which connects or disconnects the storage voltage, wherein another connection of the capacitor is to be connected to ground.

30. The memcapacitive device according to claim 22, wherein the shielding layer comprises a p-doped region and an n-doped region, and wherein the p-doped region or the n-doped region are designed to be electrically contacted via at least one switch with a bias voltage.

31. The memcapacitive device according to claim 30, wherein the memcapacitive device comprises at least one field-effect transistor integrated at least partially into the shielding layer for connecting the p-doped region and/or the n-doped region to the bias voltage.

32. The memcapacitive device according to claim 30, wherein the first electrode and/or the second electrode does not overlap with the n-or p-doped region.

33. A method for operating a memcapacitive device with an adjustable nonlinear capacitance-voltage curve, comprising:
providing:
a number of electrical connections for electrically contacting the memcapacitive device;
a first electrode;
a second electrode; and
at least one dielectric arranged between the first electrode and the second electrode, wherein the electrical connections, the first and second electrodes and/or the at least one dielectric form charge traps of varying depths for trapping variable amounts of charge; and
writing the memcapacitive device by applying a positive or negative write voltage to the first electrode and/or to the second electrode to change the amounts of charge trapped in the charge traps.

34. The method according to claim 33, further comprising setting a nonlinear capacitance-voltage curve.

35. The method according to claim 33, wherein the at least one dielectric comprises a first dielectric with a first charge trap and a second dielectric with a second charge trap.

36. The method according to claim 34, further comprising, for the memcapacitive device, providing a shielding layer arranged between the first electrode and the second electrode with a controllably variable shielding capability, and wherein setting of the nonlinear capacitance-voltage curve comprises applying a bias voltage to the shielding layer.

37. The method according to claim 35, wherein the first dielectric is arranged between the first electrode and the shielding layer and/or wherein the second dielectric is arranged between the second electrode and the shielding layer.

38. The method according to claim 36, wherein the shielding layer comprises a p-doped region and an n-doped region, and wherein the p-doped region or the n-doped region are designed to be electrically connected to a bias voltage via at least one switch, and wherein applying the bias voltage comprises applying a constant voltage in the p-doped region and/or in the n-doped region.
